(19) United States
(12) Patent Application Publication
(10) Pub. No.: US 2011/0260314 A1
(43) Pub. Date: Oct. 27, 2011

(54) DIE PACKAGE AND CORRESPONDING METHOD FOR REALIZING A DOUBLE SIDE COOLING OF A DIE PACKAGE

(75) Inventor: Agatino Minotti, Mascalucia (IT)

(73) Assignee: STMICROELECTRONICS S.R.L., Agrate Brianza (IT)

(21) Appl. No.: 13/092,757

(22) Filed: Apr. 22, 2011

(30) Foreign Application Priority Data
Apr. 27, 2010 (IT) MI2010A 000718

(51) Int. Cl. H01L 23/40; H01L 21/56

(52) U.S. Cl. 257/693; 438/122; 257/E23.083; 257/E21.504

(57) ABSTRACT

A die package is provided, including a die positioned on and in direct contact with a first heat sink element, and also including a package case and leads made of conductive material, protruding from the package case. The die package further includes a second heat sink element shaped as a spring element, in contact between the die and the leads, and emerging from a side of the package case opposite the first heat sink element.

### BACKGROUND

1. Technical Field

The present disclosure relates to a die package.

More specifically, the disclosure relates to a die package of the type comprising a die being placed on and in direct contact with a low heat sink element and having a package case as well as leads being made of conductive material, and protruding from said package case.

The disclosure also relates to a method for realizing a double side cooling of a die package.

The disclosure particularly, but not exclusively, relates to a die package of the SMD (acronym of “Surface Mount Device”) type and the following description is made with reference to this field of application for convenience of explanation only.

2. Description of the Related Art

As it is well known, in order to improve the electrical performances of an integrated device being housed into a package, in particular of a power device housed into a power package, heat removal is a key point.

In this aim, the design of the current standard power packages is made by taking into account that a low side flange (also indicated as the heat sink) whereto a power die is bonded, and in particular normally soldered, as well as Input-Output or I/O pins are connected by wire bonding. In particular, wires connect the top surface of the power die to leads, which are used to connect it with the external world.

More in particular, when considering a PowerMOSFET device, wherein a current is vertically flowing through the silicon bulk of the die comprising the device, the heat sink actually works as a heat spreader. In this case, the drain contact of the PowerMOSFET device is to be considered as a heat spreader too.

A known packaged PowerMOSFET device is schematically shown in FIG. 1, the final package being globally indicated by 1.

The package 1 in particular comprises a die 2, in turn including the PowerMOSFET device, being housed in a package case 3 and being placed in direct contact with a heat sink 4. The die 2 is connected to the external word, i.e., to the outside of the package 1, by wires, 5a and 5b, being in turn connected to leads or pins, 6a and 6b, protruding from the package case 3.

It is also known that it is possible to improve the electrical performance of a packaged die by substituting the wires by means of a metallic strap called “clip” that is soldered over the surface of the die, as schematically shown in FIG. 2, the final package being globally indicated by 7.

In this case, the package 7 comprises the die 2 which is also placed in direct contact with the heat sink 4, being for instance a flat portion of at least one lead, in particular the lead 6a. The die 2 is connected to the other lead 6b by a clip 8, which has a flat portion in direct contact with the top surface of the die 2.

In particular, the clip 8 is made of metal, normally copper (Cu), and thus substantially improves the electrical parameters of the die 2, also helping to remove the heat from the die surface whereat such heat is generated.

It can be verified that the use of a clip is normally able to decrease the thermal resistance of the package, comprising the die which is connected to this clip, by a 5-10% with respect to a similar package comprising a wire bonded die.

It is also known that the assembly process of this kind of clips needs a special coating of the contact side i.e., the front side of the silicon die, that is normally finished by a metallic layer, in particular aluminum (A1). In order to make such a surface, i.e., the front side of the silicon die, able to be soldered, it should be finished by means for instance of a so called wet metal, for example titanium-nickel-gold (Ti-Ni-Au) or chrome-nickel-gold (Cr-Ni-Au).

It is thus evident that such a special coating step would increase the cost of the silicon die.

Starting from this concept, many ideas upon the need to remove the heat from a packaged die came up in the field of semiconductor die manufacturing.

One of the most efficient method to remove heat from a packaged die is the so called “Dual side cooling”. According to this known method, the heat is dissipated from the bottom of the package housing the die, in particular through the heat sink thereof as well as from the top of the die, by adding a strap or clip soldered to the silicon top of the die, connecting it to the outside world. The exposed area of such an added strap is then attached to an external heat sink or external clip and heat is simultaneously removed from top and from bottom of the packaged die.

In particular, this external clip is biased as it is directly into contact with the silicon top surface of the die (also indicated as source). In particular, the clip is connected to an I/O terminal per die (a source terminal in this case), thus ensuring the correct biasing. It can be verified that the thermal resistance of the resulting packaged die or package is improved by 40-45% if compared to a same package with a die of identical size being cooled with a single side cooling solution of the known type, such as a die being connected to an internal clip only.

Today's power packages with double side cooling are made by soldering a metal clip, that is bonded from a top silicon surface to the package case where an external heat sink will be connected, as schematically shown in FIG. 3, the final package being globally indicated by 9.

In particular, the package 9 comprised a chip 2 being connected to an internal heat sink 4, the chip 2 being placed in direct contact with the internal heat sink 4. Moreover, the package 9 comprises a metal clip 8 being placed in direct contact, and in particular soldered, with a top silicon surface 2a of the die 2 and being in contact with the leads 6a and 6b. More in particular, the metal clip 8a has a top surface 9a that emerges from the package case 3 and can be connected to an external heat sink, not shown, in order to realize the required double side cooling.

Current methods for making a double side cooling of power packages are quite rigid and the corresponding assembly process window is very tight, thus impacting with yield and field return. As an example, the solder quantity involved in soldering the clip needs to be very much accurately dispensed so as to avoid a damage of the silicon making the dice, such a die damaging occurring if the quantity of the solder is above a maximum limit and molding compound thereof flashes. Moreover, die damaging occurs if the quantity of the solder is below a designed quantity, causing problems tied to the flatness of the final clip.

Furthermore, it is well known that the die thickness tolerance, obtained by back grinding, needs also to be accurately considered. In particular, it needs to be within +/−5 micrometers with respect to standard +/−20 micrometers of the die thickness.

In particular, the assembly process which is making dual side cooling technology possible is the molding, indeed. However, a molding process for this kind of technology is very complex and needs, in addition to basic material such as a molding compound, a foil, to be more precise, a top foil and a bottom foil, to be used. Foil material is normally a PET carrier with a glue which activates under the effect of the molding temperature.

Furthermore, the price of the machine involved in such an assembly process is very high and material involved very costly. Foil is interposed between the mold cavity and the package to mold for the following reasons:

1- Molding flashes propagation. If lower heat sink and/or upper exposed clip are covered by a layer of compound, package solderability and ability to dissipate heat would severely affected. In order to get rid of this issue, a strong flashes removal process needs to be provided.

2- Silicon chip damage. Foil is needed to absorb the difference in thickness of all the used layers. If the value of the sum of all the layers composing the package (lower heat sink, solder between heat sink and chip, chip, solder between chip and clip) is above the actual mold cavity, molding clamp pressure would break the weakest element that is the chip. Foil (normally 50-70 micrometers thick) squeezes under the effect of the clamp pressure and then works as sealer for flashes and as pressure/thickness mismatch absorber. The outcome of this process is it is very sensitive to all elements thickness and to mold design. In addition to that, foil equipped molded systems are very expensive (25% more than standard ones), with a low MTBA (acronym of “Mean Time Between Assistance”), i.e., the mean time which separates two assistance operations performed by an user which works on the system, and not very easy to maintain. Foil is also very expensive and the final package cost is strongly affected by the molding process.

Moreover, known dual side cooling packages are quite rigid in design and need to be specifically designed for this purpose.

### BRIEF SUMMARY

Some embodiments include a die package having a dual side cooling and the corresponding method having structural and functional characteristics which allow to overcome the limits which still affect the method and packages realized according to the prior art.

One embodiment includes a die package with a spring element which connects leads and a front side of a die, thus allowing a final user of the package to place an external heat sink and thus provide a dual side cooling of the die package.

One embodiment includes a die package of the type comprising a die placed on and in direct contact with a low heat sink element and having a package case as well as leads, being made of conductive material, and protruding from said package case, characterized in that it further comprises an upper heat sink element being shaped as a spring element and being in contact between said die and said leads and emerging from said package case in an opposite end with respect to said low heat sink element.

More in particular, various embodiments comprise the following supplemental and optional features, taken alone or in combination.

According to one embodiment, said upper heat sink element can be a spring shaped strap.

According to another embodiment, said upper heat sink element can comprise at least an upper portion emerging from said package case so as to act as an upper heat sink.

Moreover, according to this embodiment, said upper heat sink element can further comprise at least a low portion in contact with said die and at least a lateral portion in contact with said leads.

According to a further embodiment, said upper heat sink element can be soldered to said die.

According to yet another embodiment, said die package can further comprise a solder layer being provided at least between said die and said low heat sink element.

Moreover, according to a further embodiment, said upper heat sink element can comprise a first lateral portion connected to a first lead and a second lateral portion connected to a second lead, said leads protruding from opposite ends of said package case.

According to this embodiment, said upper heat sink element can further comprise a first low portion being in contact with said die and being also connected to said first lateral portion as well as a second low portion being also in contact with said die (and connected to said second lateral portion.

Moreover, yet according to this embodiment, said upper heat sink element can further comprise an upper portion being substantially C shaped and in contact with said first low portion and said second low portion.

Furthermore, according to this embodiment, said die package can further comprise a solder layer, in turn having a first portion being interposed between said first lateral portion of said upper heat sink element and said first lead, a second portion being interposed between said second lateral portion of said upper heat sink element and said second lead, a third portion being interposed between said first low portion of said upper heat sink element and said die, a fourth portion being interposed between said second low portion and said die as well as a fifth portion being interposed between said die and said low heat sink element.

Furthermore, according to another embodiment, said upper portion of said upper heat sink element emerging from said package case is shaped in order to leave an area of said package case free.

According to yet another embodiment, said die package can further comprise a solder layer only between said die and said low heat sink element, said first and second lateral portions of said upper heat sink element being into direct contact with said first and second leads respectively, and said first and second low portions of said upper heat sink element being into direct contact with said die.

Moreover, according to an embodiment, said upper heat sink element can comprise a single low portion being in contact with said leads and said die.

According to this embodiment, said die package can further comprise a solder layer between said upper portion and said single low portion of said upper heat sink element.

One embodiment is a method for realizing a double side cooling of a die package comprising the steps of:

providing a die package comprising a low heat sink element;

providing conductive leads; and

placing a die on and in direct contact with said low heat sink element,

providing an upper heat sink element in contact with said die and said leads and having at least an upper portion, said upper heat sink element being shaped as a spring element; and

molding a package case made of insulating material and including said die, said upper heat sink element and said low heat sink element in such a way that said conductive leads protrude from said package case and said upper portion of said upper heat sink element emerges from said package case of a so obtained die package in an opposite end with respect to said low heat sink element.

According to another embodiment, said method can further comprise a step of placing an external heat sink in contact with said upper heat sink element.

Moreover, according to another embodiment, said method can further comprise a step of providing a solder layer, being interposed at least between said die and said low heat sink element.

Finally, according to this embodiment, said step of providing said solder layer can realize portions of said solder layer being interposed between said upper heat sink element, said leads and said die, respectively.

The characteristics and advantages of the die package and the method according to various embodiments will be apparent from the following description of an embodiment thereof given by way of indicative and non limiting example with reference to the annexed drawings.

### BRIEF DESCRIPTION OF THE SEVERAL VIEWS OF THE DRAWINGS

In such drawings:

FIG. 1 schematically shows a package including a PowerMOSFET device, being realized according to the prior art;

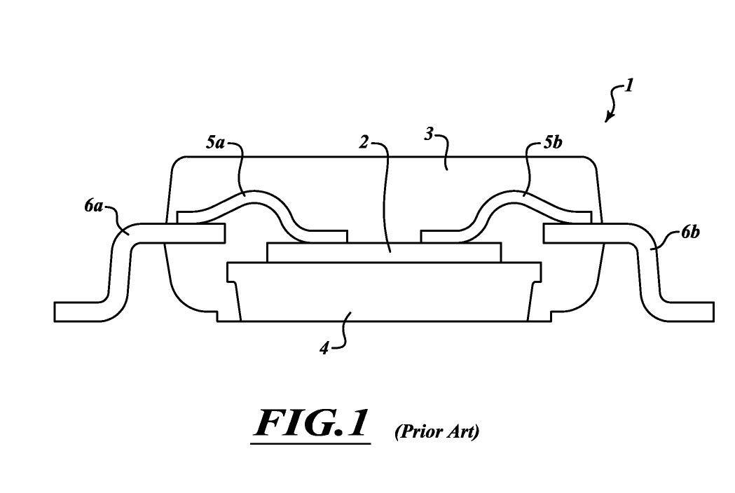

FIG. 2 schematically shows, a package comprising a die being connected to a clip and being realized according to the prior art;

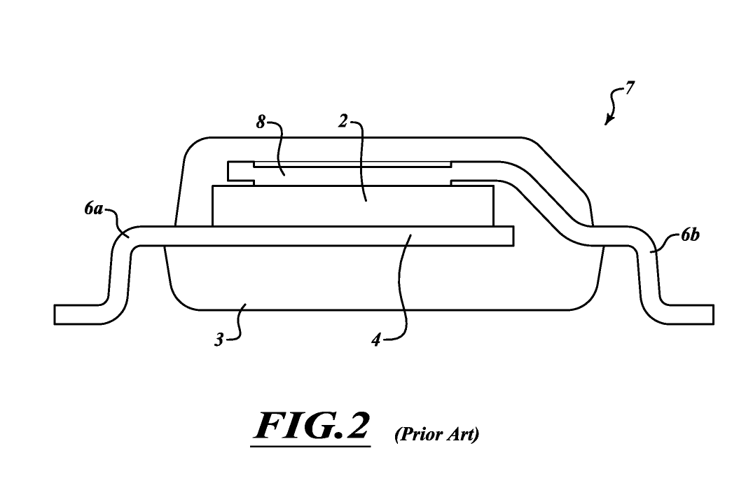

FIG. 3 schematically shows a package comprising a metal clip for providing a double side cooling according to the prior art;

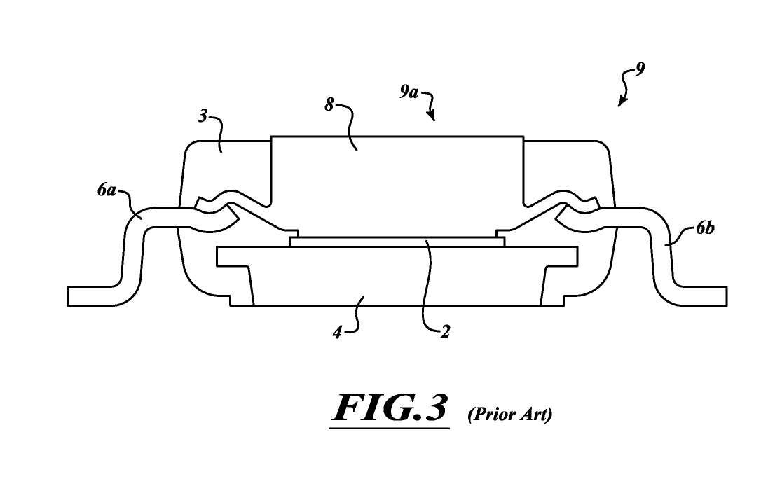

FIG. 4 schematically shows a lateral view of a die package having a double side cooling according to an embodiment;

FIG. 5 schematically shows a top view of the die package of FIG. 4;

FIG. 6 schematically shows an alternative embodiment of a die package having a double side cooling according to an embodiment; and

FIG. 7 schematically shows a further alternative embodiment of a die package having a double side cooling according to an embodiment.

### DETAILED DESCRIPTION

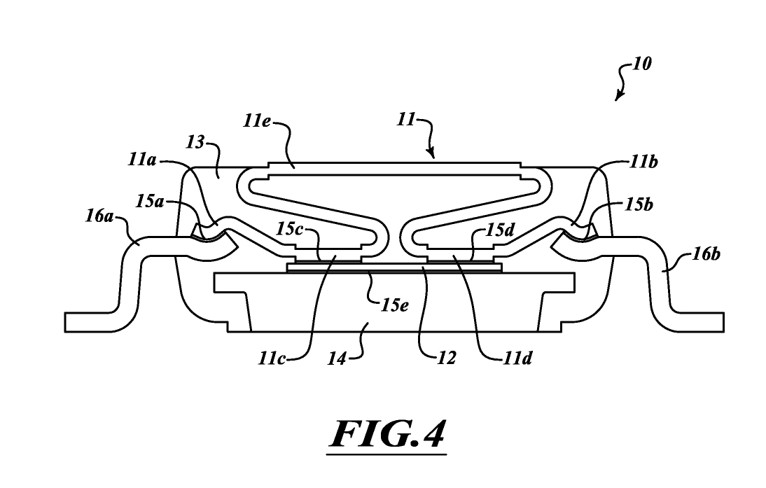

With reference to such figures, and in particular to FIG. 4, a package comprising at least one die, also indicated as die package is shown and globally indicated with 10. As will be clear from the following description, advantageously according to an embodiment, the die package has a dual side cooling.

It should be noted that the figures show schematic views of the die package and are not drawn in scale, being on the contrary drafted so as to emphasize the important features of the illustrated embodiment.

The die package 10 comprises a die 12 being placed on and in direct contact with a low heat sink element 14 and has a package case 13 made of insulating material, in particular of plastic material. Leads 16a, 16b, being made of conductive material, in particular of Copper (Cu), protrude from the package case 13.

Advantageously according to an embodiment, the die package 10 also comprises an upper heat sink element 11, in particular shaped as a spring element.

More in particular, the upper heat sink element 11 comprises at least a low portion in contact with the die 12, at least a lateral portion in contact with at least one lead and an upper portion emerging from the package case 13 so as to act as an upper heat sink.

In essence, the upper heat sink element 11, being a strap which is “spring” shaped, is soldered into the die package 10 and connects a front side or surface of the die 12, leads 16a and 16b and the external world, i.e., the outside of the die package 10.

Also advantageously according to an embodiment, the die package 10 can also comprise a solder layer 15 being provided at least between the die 12 and the low heat sink element 14 and in case between the die 12 and the low portion of the upper heat sink element 11 as well as between lateral portions of the upper heat sink element 11 and the leads 16a and 16b.

According to the embodiment shown in FIG. 4, the upper heat sink element 11 comprises a first lateral portion 11a connected to a first lead 16a and a second lateral portion 11b connected to a second lead 16b, the leads 16a and 16b protruding from opposite ends of the package case 13.

Moreover, the upper heat sink element 11 comprises a first low portion 11c being in contact with the die 12 and being also connected to the first lateral portion 11 a as well as a second low portion 11d being also in contact with the die 12 and connected to the second lateral portion 11b. Finally, the upper heat sink element 11 comprises an upper portion 11e being substantially C shaped, in contact with the first low portion 11c and the second low portion 11d and emerging from the package case 13 in an opposite end with respect to the low heat sink element 14.

The upper heat sink element 11 is thus a profiled strap, in particular being made of metallic material and free to be compressed under the effect of mold clamps which are to be used to realize the package case 13.

In other words, advantageously according to an embodiment, the upper heat sink element 11 being spring shaped adapts itself to the thicknesses of the several components or layers comprised into the package case 13, as the low heat sink element 14 and the die 12, and in case the solder layer 15, as well as to the relevant tolerances.

According to the embodiment shown in FIG. 4, the die package 10 also comprises a solder layer 15, in turn having a first portion 15a being interposed between the first lateral portion 11a of the upper heat sink element 11 and the corresponding first lead 16a, a second portion 15b being interposed between the second lateral portion 11b of the upper heat sink element 11 and the corresponding second lead 16b, a third portion 15c being interposed between the first low portion 11c of the upper heat sink element 11 and the die 12, a fourth portion 15d being interposed between the second low portion 11d and the die 12 as well as a fifth portion 15e being interposed between the die 12 and the low heat sink element 14.

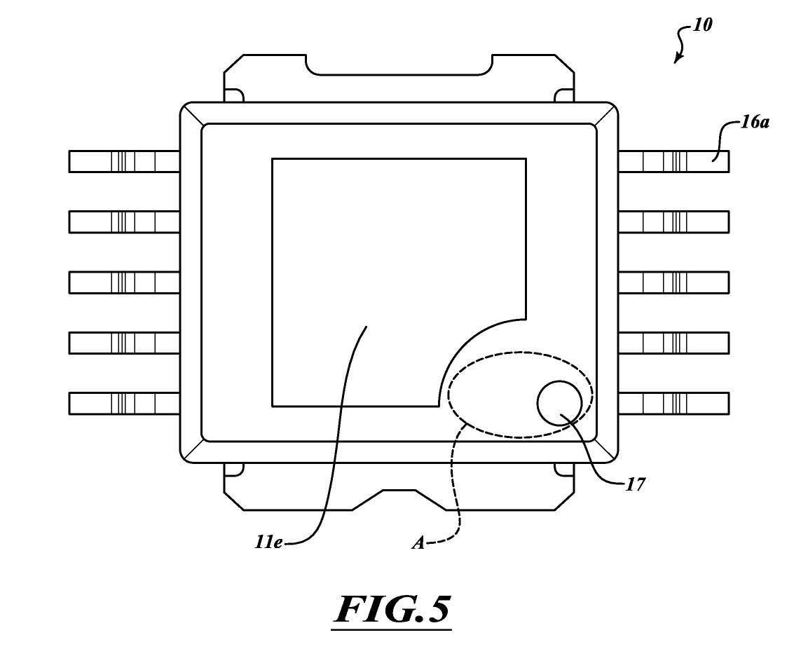

The die package 10 according to an embodiment is also shown in FIGS. 4 and 5, according a lateral view and a top view, respectively. In particular, as shown in FIG. 5, the upper portion 11e of the upper heat sink element 11 is suitably shaped in order to leave an area A of the package case 13 free, such an area being used to place for instance a bonding wire 17. For instance, the upper heat sink element 11 is shaped since one of the three I/O terminals of the PowerMOS device a gate terminal, which is to be contacted by a wire bonding, the free area A being needed by the wire bonding tool.

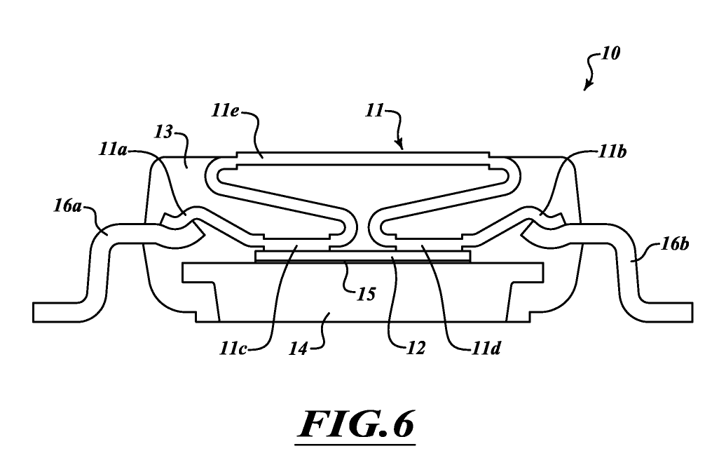

According to an alternative embodiment, the die package 10 only comprises the solder layer 15 between the die 12 and the low heat sink element 14, the first lateral portion 11a of the upper heat sink element 11 being into direct contact with the corresponding first lead 16a, the second lateral portion 11b of the upper heat sink element 11 being into direct contact with the corresponding second lead 16b, the first low portion 11c of the upper heat sink element 11 being into direct contact with the die 12 and the second low portion 11d being into direct contact with the die 12, as shown in FIG. 6. In this case, the upper heat sink element 11 is no longer soldered onto the die 12 but it is only touching its surface and firmly pressed by the molding process.

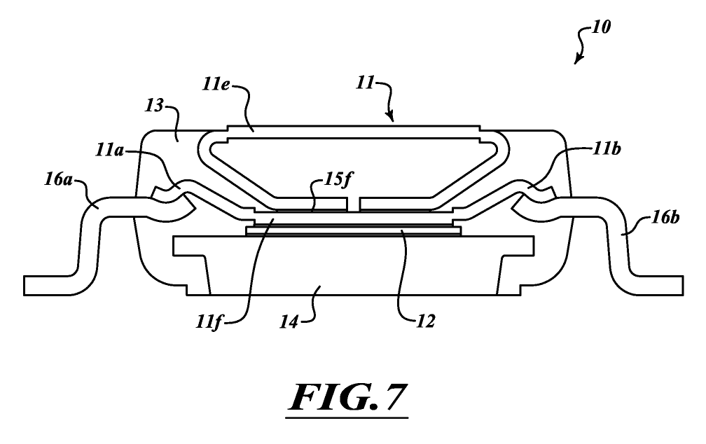

Moreover, according to a further alternative embodiment, the upper heat sink element 11 comprises a single low portion 11f, being in contact with the leads 16a and 16b and the die 12, and being in case separated to the upper portion 11e by a further portion 15f of the solder layer 15, as shown in FIG. 7.

An embodiment also relates to method for realizing a double side cooling of a die package 10 comprising the steps of:

providing a die package 10 comprising a low heat sink element 14;

providing conductive leads 16a, 16b; and

placing a die 12 on and in direct contact with the low heat sink element 14.

Advantageously according to an embodiment, the method also comprises the steps of:

providing an upper heat sink element 11 in contact with the die 12 and the leads 16a, 16b and having at least an upper portion 11e, such a upper heat sink element 11 being shaped as a spring element; and

molding a package case 13 made of insulating material and including the die 12, the upper heat sink element 11 and the low heat sink element 14 in such a way that the conductive leads 16a, 16b protrude from the package case 13 and the upper portion 11e emerges from the package case 13 of the die package 10.

In this way, the upper heat sink element 11, being “spring” shaped, is free to be compressed under the effect of the molding step in order to compensate the clamping effect and obtain a flat upper side of the die package 10. Moreover, the free compression of the “spring” shaped upper heat sink element 11 ensures no damage on the die 12.

The method further comprises a step of placing an external heat sink in contact with the upper heat sink element 11, thus improving the dual side cooling of the die package 10.

Finally, the method can further comprise an optional step of providing a solder layer 15, being interposed at least between the die 12 and the low heat sink element 14 and preferably having portions 15a, 15b, 15c, 15d being interposed between the upper heat sink element 11 and the leads 16a, 16b and the die 12, respectively.

In summary, advantageously according to an embodiment, even mismatch among the layers, leading to planes tilting, will be “flattened” and exposed package surface, in particular the upper portion 11e of the upper heat sink element 11, which is the second side the heat is dissipated, will always be flat.

This is achieved by designing the upper heat sink element 11 as a profiled clip being always in interference with a mold cavity of the die package 10 as it closes.

In particular, it should be remarked that interference will ensure very low compound flash propagation and the spring effect of the so shaped upper heat sink element 11 will ensure no damage on the die 12.

In addition to that it can be verified, for instance by a FEM analysis, that the die package 10 according to an embodiment shows an excellent behavior, when compared to a standard package, under power/thermal cycles (measured in cycles) where the stress on the die 12 and solder layer 15 is induced by thermal expansion/contraction of all the elements comprised into the die package 10.

In particular, such an analysis, being realized by the applicant, showed an improvement equal to 15-20% with respect to a standard package.

From an assembly process point of view, advantageously according to an embodiment all assembly process steps are simplified and standard existing equipment can be used as well. As an example, solder paste dispensed quantity, as well as the die thickness tolerance are no longer an issue as the final compensation is given by the spring effect of the upper heat sink element 11.

In particular, the main assembly process of the die package 10 according to an embodiment is always mold. However, advantageously according to an embodiment, top and bottom foils are no longer needed and standard mold can be used. The above described interference would control flash propagation and will not cause stress/damage on the die 12.

That turns into low investment for equipment, for material and less rigidity in package design.

In addition to that, many current packages can be easily changed from single to dual side cooling with very limited investment on material/equipment.

Advantageously according to one embodiment, the only requirement is to provide the package with an upper heat sink element 11 being a dedicated spring clip and silicon chip design. In particular, it is well known that the geometry of the die surface (the metalized one) and the chip surface being soldered thereon should be designed in accordance one another.

Moreover, according to the first alternative embodiment shown in FIG. 6, also removing solder layer portions as described, it can be verified that the contact is ensured through molding compound shrinkage (normally from 0.3% to 1%).

This will further improve thermal resistance of the die package 10 of FIG. 6 of about 2-3% with respect to the die package 10 according to the embodiment of FIGS. 4 and 5. In addition to that, the so called wet metal is no longer needed as the upper heat sink element 11 is no longer soldered onto the die 12 but it is only touching its surface and firmly pressed by the mold shrinkage. This process will allow die cost to dramatically decrease.

Finally, according to the second alternative embodiment of FIG. 7, the upper heat sink element 11 being split in two pieces, the design of such upper heat sink element 11 is made simpler, the overall cost of the die package 10 being thus further lowered.

It should be noted that, event packages of the SMD (acronym of “Surface Mount Device”) have been considered, also through hole and other types of packages may profit as well of the proposed upper heat sink element 11 realizing a dual side cooling mechanism for the die package 10.

In essence, the die package 10 comprising the upper heat sink element 11 shaped as a spring element would resolve all process and assembly issues by considering a spring elements which connect leads and a surface of the die 12 as well the package case 13, allowing a final user to further place an external heat sink and realize the double side cooling of the die package 10.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A die package, comprising:
a package case;
a first heat sink element enclosed within the package case;
a die positioned on and in direct contact with the first heat sink element and enclosed within the package case;
an electrically conductive first lead protruding from said package case; and
a second heat sink element, shaped as a spring element, in thermal contact with said die .

2. The die package according to claim 1, wherein said second heat sink element is a spring shaped strap.

3. The die package according to claim 1, wherein said second heat sink element comprises at least a first portion emerging from said package case.

4. The die package according to claim 3, wherein said second heat sink element further comprises at least a second portion in contact with said die and at least a third portion in contact with said first lead.

5. The die package according to claim 4, wherein said second and third portions of said second heat sink element are integral to a single heat sink component of said second heat sink element in contact with said leads and said die.

6. The die package according to claim 5, comprising a solder layer between said first portion and said single heat sink component of said second heat sink element.

7. The die package according to claim 3, wherein said first portion of said second heat sink element emerging from said package case is shaped in order to leave an area of said package case free.

8. The die package according to claim 1, wherein said second heat sink element is soldered to said die.

9. The die package according to claim 1, comprising a solder layer positioned between said die and said first heat sink element.

10. The die package according to claim 1, wherein said second heat sink element comprises a first portion connected to said first lead and a second portion connected to an electrically conductive second lead, said first and second leads protruding from opposite ends of said package case.

11. The die package according to claim 10, wherein said second heat sink element further comprises a third portion in contact with said die and connected to said first portion, and also comprises a fourth portion in contact with said die and connected to said second portion.

12. The die package according to claim 11, wherein said second heat sink element further comprises a fifth portion being substantially C shaped and in contact with said first portion and said second portion.

13. The die package according to claim 12, comprising a solder layer, in turn having a first portion interposed between said first portion of said second heat sink element and said first lead, a second portion interposed between said second portion of said second heat sink element and said second lead, a third portion interposed between said third portion of said second heat sink element and said die, a fourth portion interposed between said fourth portion of said second heat sink element and said die as well as a fifth portion interposed between said die and said first heat sink element.

14. The die package according to claim 12, comprising a solder layer positioned between said die and said first heat sink element, said first and second portions of said upper heat sink element being in direct contact with said first and second leads respectively, and said third and fourth portions of said second heat sink element being in direct contact with said die.

15. A method for realizing a double side cooling of a die package comprising:
providing a low heat sink element;
providing conductive leads;
placing a die on and in direct contact with said low heat sink element, providing an upper heat sink element in contact with said die and said leads and having an upper portion shaped as a spring element; and
molding a package case made of electrically insulating material at least partially encapsulating said upper heat sink element and said low heat sink element in such a way that said conductive leads protrude from said package case and said upper portion of said upper heat sink element emerges from said package case at a surface thereof

16. The method of claim 15, comprising placing an external heat sink in contact with said upper heat sink element.

17. The method of claim 16, comprising providing a solder layer interposed between said die and said low heat sink element.

18. The method of claim 17, wherein providing said solder layer comprises providing portions of said solder layer between said upper heat sink element and said leads, and between said upper heat sink element and said die, respectively.

19. A device, comprising:
an package of an electrically insulating material;
a semiconductor material die fully encapsulated within the package;
a plurality of electrical leads partially encapsulated within the package and extending therefrom, each in electrical contact with the die; and
a first thermally conductive heat sink element shaped as a spring and positioned with a first portion in close thermal contact with a first surface of the die and a second portion exposed at a first face of the package.

20. The device of claim 19, comprising a solder joint coupling the first portion of the first heat sink element to the die and configured to transmit heat from the die to the first heat sink element.

21. The device of claim 19, comprising a first solder joint coupling the first heat sink element to the die and a second solder joint coupling the first heat sink element to one of the plurality of electrical leads, the first and second solder joints and the first heat sink element together configured to electrically couple the one of the plurality of leads to the die.

22. The device of claim 19, comprising a second heat sink element positioned with a first portion thereof in close thermal contact with a second surface of the die opposite the first surface of the die, and a second portion exposed at a second face of the package opposite the first face of the package.

23. A method, comprising:
positioning a semiconductor die in a molding cavity;
positioning a plurality of leads in the molding cavity;
positioning a first heat sink in the molding cavity in physical contact with the semiconductor die;
closing the molding cavity and applying clamping pressure, thereby compressing the first heat sink between a wall of the molding cavity and a surface of the semiconductor die; and
forming a semiconductor package by introducing a quantity of molding compound into the molding cavity.

24. The method of claim 23, comprising positioning a second heat sink in the molding cavity in physical contact with the semiconductor die on a side of the die opposite the first heat sink.

25. The method of claim 23, comprising soldering the first heat sink to the semiconductor die.

26. The method of claim 23, comprising soldering the first heat sink to each of the plurality of leads.

27. The method of claim 23 wherein positioning a first heat sink in the molding cavity comprises positioning the first heat sink in the molding cavity in electrical and physical contact with the semiconductor die and in electrical contact with each of the plurality of leads.

28. The method of claim 23 wherein positioning a first heat sink in the molding cavity comprises positioning a lower portion of the first heat sink in the molding cavity in electrical and physical contact with the semiconductor die and in electrical contact with each of the plurality of leads, and positioning an upper portion of the first heat sink in the molding cavity in physical contact with the lower portion of the first heat sink.
